(19) United States
(12) Patent Application Publication
(10) Pub. No.: US 2014/0301576 A1
(43) Pub. Date: Oct. 9, 2014

(54) Adjustable audio splitter

(71) Applicant: Michael Lacorte, Oro Valley, AZ (US)

(72) Inventor: Michael Lacorte, Oro Valley, AZ (US)

(21) Appl. No.: 13/986,137

(22) Filed: Apr. 4, 2013

(51) Int. Cl. H03F 99/00

(52) U.S. Cl. CPC H03F 21/00
USPC 381/120

(57) ABSTRACT

An audio splitter receiving an incoming electrical signal defining an audio signal. The audio splitter receives an incoming signal and creates at least two identical channels having the same incoming signal. Each channel has a manually controlled amplifier. By manipulating the manually controlled amplifier, the operator is able to selectively magnifying the electrical signal within the channel. This allows the operator to adjust the intensity or “loudness” of the signal being generated as output within the channel.

### BACKGROUND OF THE INVENTION

This invention relates generally to electronics and more particularly to a splitter for audio signals.

The use of video and audio apparatus has become widespread. Although originally designed for individual use, often friends or families tend to share a single device as a form of companionship in jointly enjoying the video, music, or other audio component. In a quiet environment, the audio portion is adjusted to meet the needs of the group or audience, but, in a noisy environment or where a level of privacy is sought, ear phones are used and the audio signal is passed through a “splitter”.

The “splitter” takes the incoming audio electrical signal and creates multiple channels having identical electrical signals. These channels are then “tapped” by the earphones of the individual users so that all can independently listen. In essence, the splitter produces multiple identical audio channels from a single input.

While the existing “splitter” does allow multiple “listeners”, all too often the interests or physical characteristics (e.g. hard of hearing) of the individual listeners varies so that the resulting sound being generated is a “Goldilocks” situation, too loud, too soft, or just right.

This causes frustration between the users and cannot be properly addressed.

It is clear there is a need for improved audio splitting capability.

### SUMMARY OF THE INVENTION

The invention is an audio splitter which receives an incoming electrical signal defining an audio signal. These audio signals are often associated with portable players which have stored the music, book reading, poetry, or lectures electronically allowing the user to playback any of the assorted material contained in the memory. Similar types of devices allow the audio portion of a movie to be heard over earphones.

Typically the portable player includes a jack that accepts an electrical plug that communicates the electrical signal to a speaker, headphones, earphones or the like. The present invention includes a connection which serves as a channel between the portable player and the present audio splitter.

The audio splitter takes the incoming signal and creates multiple identical signals therefrom. These signals are all communicated through their own channel. Each channel contains a manually adjustable amplifier which boosts or diminishes the signal.

Those of ordinary skill in the art readily recognize a variety of amplifiers which will work in this capacity, including, but not limited to those described in U.S. Pat. No. 8,284,960, entitled “User Adjustable Volume Control that Accommodates Hearing” issued to Vaudrey et al. on Oct. 9, 2012; U.S. Pat. No. 8,351,620, entitled “Volume Adjuster” issued to Arakawa on Jan. 8, 2013; and, U.S. Pat. No. 8,379,839, entitled “Method and Apparatus for Controlling Ringing Voltage” issued to Nagarajaiah et al. on Feb. 19, 2013; all of which are incorporated hereinto by reference.

The now amplified signal is communicated to a connector which is usable by a speaker, headphones, earphones or the like.

Those of ordinary skill in the art readily recognize a variety of apparatus which serves as receivers or speakers in this context, including, but not limited to: U.S. Pat. No. 8,380,125, entitled “Systems and Methods for Bluetooth Resource Conservation” issued to Kirbas on Feb. 19, 2013; U.S. Pat. No. 8,379,894, entitled “Hearing Aid wi5th Adaptive Feedback Suppression” issued to Klinkby on Feb. 19, 2013; and U.S. Pat. No. 4,665,559, entitled “FM-TV Audio Adapter” issued to Benun on May 12, 1987; all of which are incorporated hereinto by reference.

Using headphones, a number of users, each with their own headphone are able to manually adjust the signal via their own assocaited amplifier to their own headphone to obtain a volume that suits their tastes or physical demands.

One embodiment of the invention also provides for the individual manual adjustment of the bass/treble component in the audio signal. This embodiment allows different users having different tastes as to the “proper balance” to the music to listen to their own self-defined “balance”.

Those of ordinary skill in the art readily recognize a variety of bass/treble mechanisms which can be used in this context, including, but not limited to those described in U.S. Pat. No. 8,295,494, entitled “Enhancing Audio with Remixing Capability” issued to Oh et al. on Oct. 23, 2012; and, U.S. Pat. No. 8,275,152, entitled “Dynamic Bass Boost Filter” issued to Smirnov et al. on Sep. 25, 2012; both of which are incorporated hereinto by reference.

In an embodiment of the audio splitter of the invention is contained within a single housing and is ideally hand sized for easier transportation and use. Ideally, a rechargeable battery is also contained within the housing to power the manually adjustable amplifiers.

Recharging the battery is accomplished either through the use of a mechanism external to the housing or using an internally mounted charger. In some situations, the naturally occurring electricity from the input channel is used to maintain the battery charge by using this electricity when the unit is not being used to generate output signals.

Those of ordinary skill in the art readily recognize a variety of techniques which may be used to recharge the battery, including but not limited to: U.S. Pat. No. 8,380,998, entitled “Inductive Receivers for Electrical Devices” issued to Azancot et al. on Feb. 19, 2013, incorporated hereinto by reference.

In some embodiments of the invention, the amplified signals are communicated via radio waves, thereby allowing the users with their own receivers to listen without being “tethered” to the unit.

Those of ordinary skill in the art readily recognize a variety of broadcasting technologies which will work in this context, including, but not limited to: U.S. Pat. No. 8,290,168, entitled “Audio Broadcast Processing Method” issued to Blaszezynski et al. on Oct. 16, 2012; U.S. Pat. No. 4,750,206, entitled “Adapter for TV Stereo, SAP and Auxiliary Signals” issued to Schotz on Jun. 7, 1988; U.S. Pat. No. 6,185,305, entitled “Method and System for Broadcasting Digital Audio to a Radio” issued to Reinold et al. on Feb. 6, 2001; and U.S. Pat. No. 6,335,768, entitled “Method and System for Broadcasting Digital Audio and Video to an Analog Wireless Device” issued to Reinold et al. on Jan. 1, 2002; all of which are incorporated hereinto by reference.

The invention, together with various embodiments thereof, will be more fully explained by the accompanying drawings and the following description.

### DRAWINGS IN BRIEF

FIG. 1 is a block diagram of the preferred embodiment of the invention.

FIG. 2 is a perspective view of the preferred embodiment being held by a user.

FIG. 3 illustrates the invention in communication with a variety of receivers.

### DRAWINGS IN DETAIL

FIG. 1 is a block diagram of the preferred embodiment of the invention.

Handheld housing 11 communicates, via connector 10, the incoming audio electrical signal from the source of the audio electrical signal (not shown). The audio electrical signal goes through splitter 12 forming, in this illustration, three identical signals which are communicated to amplifiers 14A, 14B, and 14C. Please note that in the illustration, the handheld housing is not to scale and it is contemplated that the housing is much smaller to facilitate transportation and storage.

Note that the invention is not intended to be limited three channels as illustrated in this figure; rather the invention addresses any number of channels being two and more

Amplifiers 14A, 14B, and 14C are manually adjustable allowing the user to modify the amplification being applied to each of the channels.

In this embodiment, the now amplified signals are communicated to mixers 15A, 15B, and 15C which allow the user to modify the treble/bass components of the signals. In this manner, the user is able to have complete control not only of the volume (via amplifiers 14A, 14B, and 14C) but the sound quality (via mixers 15A, 15B, and 15C) so that the signals being communicated to connectors 16A, 16B, and 16C are unique and definable by the user(s) to meet their own tastes.

Although this embodiment illustrates the use of mixers 15A, 15B, and 15C, the invention is not so limited and in some embodiments, mixers 15A, 15B, and 15C are absent all together allowing the amplified signals to be communicated directly to connectors 16A, 16B, and 16C.

In this illustration “slide” type of switches for the amplifiers and the mixers; the invention is not to be limited to only these types of switches but also include a variety of switches obvious to those of ordinary skill in the art including, but not limited to: rotational, toggle, and rocker type of switches.

In yet other embodiments of the invention, a Radio Frequency (RF) transmitter 17 is used to communicate the signal via radio signals to a remote audio generator (not shown). Examples of this remote audio generator are well known in the art and include such items as wireless head sets and wireless ear phones.

Battery 13 is used to power the system. Charging of battery 13, in this illustration, is via connector 18. Such recharging of a battery is well known in the art. The recharger (not shown) is ideally external to handheld housing 11 although some embodiments of the invention utilize a charging unit that is contained within handheld housing 11.

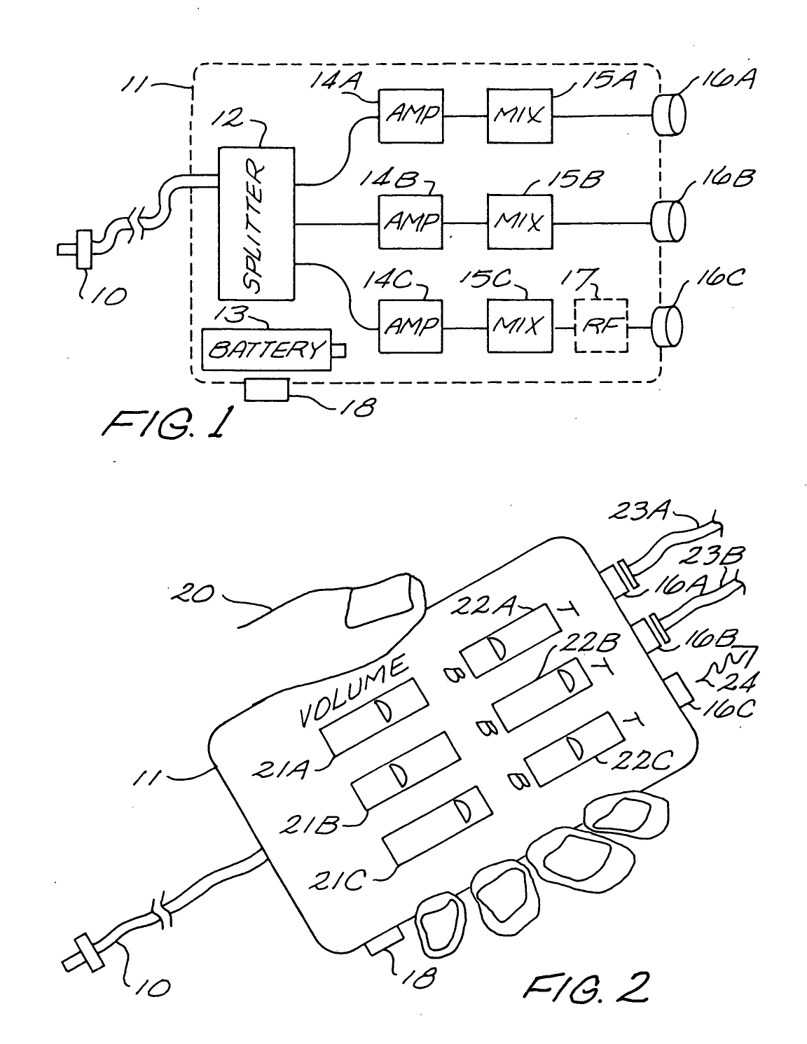

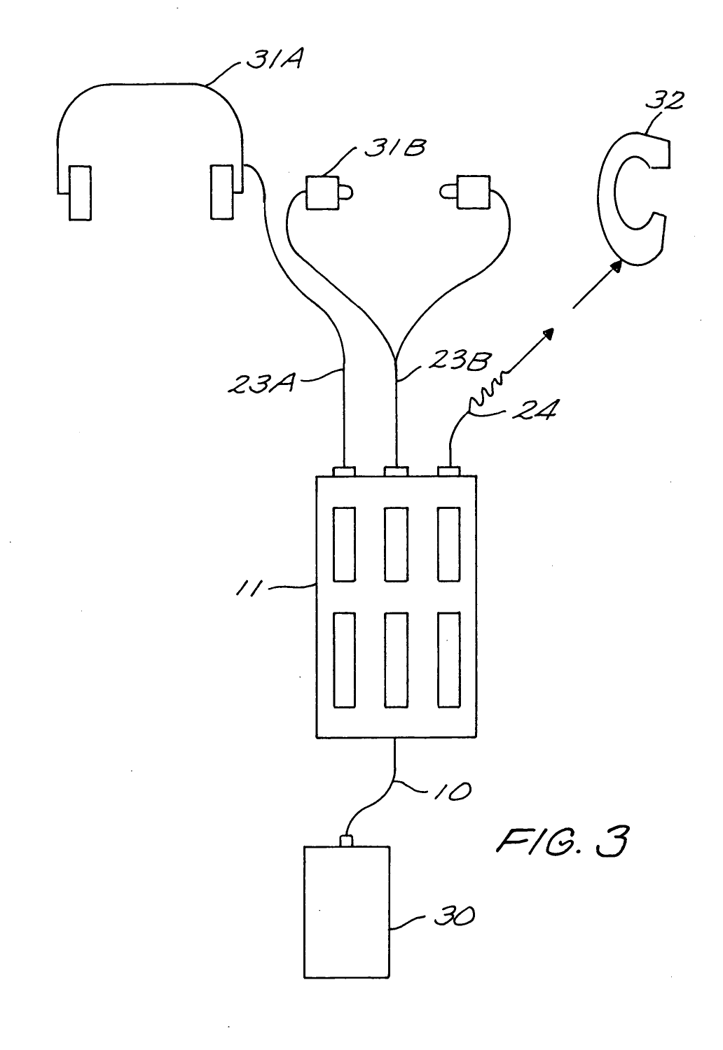

Another embodiment utilizes a replaceable battery to power the system. FIG. 2 is a perspective view of the preferred embodiment being held by user 20. Handheld housing 11 receives the incoming audio electrical signal via connector 10. This signal is then split as outlined above.

User 20, or other parties, is able to manually adjust the volume via amplifier slide switches 21A, 21B, and 21C which control their respective amplifiers (not shown in this illustration). After amplifier slide switches 21A, 21B, and 21C, the signals are then adjusted via treble/bass slide switches 22A, 22B, and 22C which control the mixers (not shown) to define the bass/treble components of the amplified signals.

The now defined signals are communicated to connectors 16A, 16B, and 16C which allow audio generators (not shown) to be connected via wires 23A and 23B. Connector 16C, in this illustration, generates a radio signal 24 which is communicated to a wireless audio generator.

In this manner, the user defined signals are communicated not only to connected audio generators via wires, but also to wireless audio generators.

FIG. 3 illustrates the invention in communication with a variety of receivers.

Audio signal generator 30 produces an audio electrical signal which is communicated to housing 11 via connection 10. The audio signal generator 30 is any of many devices well known to those skilled in the art. One such audio signal generator 30 stores music in digital form and is then withdrawn/played as per the instructions of the user.

The audio electrical signal is amplified and mixed by the electronics within housing 11 as outlined above, and communicated via wire 23A to headphones 31A and via wire 23B to ear phones 31B for the entertainment of their associated users.

Radio signal 24 communicates the user defined signal to wireless earphone 32 for that user's entertainment.

It is clear that the present invention provides for a highly improved splitter for audio equipment.

What is claimed is:

1. An audio splitter comprising:
a) an input connector configured to receive an electrical signal defining an audio signal;
b) a signal splitter receiving the electrical signal from the input connector and creating at least two channels having the electrical signal therein;
c) at least two amplifiers, each amplifier associated with one of said channels and capable of selectively magnifying the electrical signal within said channel; and,
d) at least two output connectors, each output connector receiving a signal from one of said amplifiers.

2. The audio splitter according to claim 1, wherein each of said output connectors is adapted to communicate an output signal to a selected audio generator.

3. The audio splitter according to claim 2, further including a handheld housing containing said signal splitter, said at least two amplifiers, and said at least two output connectors.

4. The audio splitter according to claim 3, further including a battery source providing electricity to each of said at least two amplifiers and wherein said battery source is contained within said housing.

5. The audio splitter according to claim 4, further including a charging mechanism adapted to communicate electricity to said battery source.

6. The audio splitter according to claim 5, wherein said charging mechanism is contained within said housing.

7. The audio splitter according to claim 5, wherein said charging mechanism draws electricity from an external source.

8. The audio splitter according to claim 5, wherein said charging mechanism draws electricity from the electrical signal received from the input connector.

9. The audio splitter according to claim 1, wherein each of said output connectors includes a radio transmitter, each radio transmitter broadcasting on a defined frequency.

10. The audio splitter according to claim 9, further including at least two radio receivers, each of said at least two radio receivers adapted to receive signals at a defined frequency corresponding to the defined frequency of one of said radio transmitters.

11. An audio splitter comprising:
a) a signal splitter creating at least two identical signals of an electrical signal for the creation of audio; and,
b) at least two amplifiers, each amplifier associated with one of said identical signals.

12. The audio splitter according to claim 11, further including at least two signal modifiers, each signal modifier addressing a single channel and capable of adjusting a treble and bass component of each electrical signal.

13. The audio splitter according to claim 12, further including a housing containing said signal splitter, said at least two amplifiers, and said at least two signal modifiers.

14. The audio splitter according to claim 12, further including a battery source providing electricity to each of said at least two amplifiers, and wherein said battery source is contained within said housing.

15. The audio splitter according to claim 14, further including a charging mechanism adapted to communicate electricity to said battery source.

16. The audio splitter according to claim 15, wherein said charging mechanism is contained within said housing.

17. An audio splitter receiving an incoming electrical signal defining an audio signal, said audio splitter comprising:
a) a signal splitter creating least two channels containing electrical signals identical to the incoming electrical signal;
b) at least two manually controlled amplifiers, each manually controlled amplifier associated with one of said channels and capable of selectively magnifying the electrical signal within said channel; and,
c) at least two output mechanisms, each output mechanism receiving a signal from one of said manually controlled amplifiers.

18. The audio splitter according to claim 16, further including:
a) a battery source providing electricity to each of said at least two amplifiers; and,
b) a handheld housing containing said signal splitter, said at least two amplifiers, said at least two output mechanisms, and said battery source.

19. The audio splitter according to claim 17, wherein each of said output mechanisms connectors includes a radio transmitter, each radio transmitter broadcasting on a defined frequency.
